(19) United States
(12) Patent Application Publication
(10) Pub. No.: US 2003/0209423 A1
(43) Pub. Date: Nov. 13, 2003

(54) System for driving multiple magnetrons with multiple phase ac

(76) Inventor: David J. Christie, Fort Collins, CO (US)

Correspondence Address: Benjamin Hudson Jr, Advanced Energy Industries Inc, 1625 Sharp Point Drive, Fort Collins, CO, 80525, US

(21) Appl. No.: 10/240,692

(22) PCT Filed: Mar. 27, 2001
(86) PCT No.: PCT/US01/09735

(51) Int. Cl. C23C 14/32

(52) U.S. Cl. 204/192.12; 204/298.08; 204/298.06

(57) ABSTRACT

There is provided by this invention a novel method of reactive sputter deposition of a thin film on a substrate (28) utilizing multiphase AC power supplies to drive multiple magnetron targets (22, 24, 26) in a plasma chamber (20) to independently regulate power to each target (22, 24, 26) wherein the voltages on the targets (22, 24, 26) are periodically reversed such that periodically at least one target (22, 24, 26) at a given time acts as an anode collecting electrons when its voltage is positive relative to the plasma (16) while the other targets (22, 24, 26) act as cathodes collecting ions when their voltage is negative relative to the plasma. A DC bias can be connected to the AC power sources wherein by changing the bias, the energy and flux of ions and electrons to the substrate (28) can be changed to increase the density of the deposited film and its refractive index, and alter the morphology and stress of the film.

### CROSS-REFERENCE TO RELATED APPLICATIONS

This application is related to and claims the benefit of priority of the commonly assigned provisional application Serial No. 60/194,470 filed Apr. 4, 2000, the contents of which are incorporated herein by reference.

### BACKGROUND OF THE INVENTION

1. Field of the Invention

This invention relates to the field of magnetron systems. Specifically, it provides a method and system for driving multiple groups of magnetrons with multiple phase AC power to sputter deposit an insulating material on a substrate in a continuous mode.

2. Brief Description of the Prior Art

Plasma deposition systems are commonly configured as shown in FIG. 1, with two magnetrons driven by an AC generator, electrically isolated from the plasma chamber. This technique was described by Este and Westwood in 1988, J. Vac. Sci. Technology A6(3) May/June 1988, pgs. 1845-1848. Now it is commonly referred to as dual magnetron sputtering or dual cathode sputtering. In this configuration an AC power supply 10 is connected to the magnetrons 12 and 14. The magnetron 12 will act as the anode for the magnetron 14 when the voltage between the magnetrons is such that magnetron 12 is positive with respect to the magnetron 14. Similarly, magnetron 14 will act as the anode for the magnetron 12 when the voltage between the magnetrons is such that the magnetron 14 is positive with respect to 12. The AC source causes any thin films deposited on the anodes to be sputtered away when the magnetrons alternatively turn negative. The plasma 16 in the chamber causes a thin film to be deposited on the substrate 18. The plasma chamber 20 is grounded. These configurations are used in the coating of large sheets of glass for architectural applications, such as “low-e” glass, and in the coating of plastic films used in food packaging and for stick-on glare reduction filters.

The advantage of this approach is primarily in reactive sputtering applications, where a metal or semiconductor is sputtered in the presence of a reactive gas. The gas then combines with conductive sputtered material to form a dielectric. This dielectric tends to be deposited on the sputtering target and anode as well as the work piece, resulting in an insulating coating on both which will eventually degrade and perhaps even shut down the process. This degradation is primarily due to an effect that is referred to as a “disappearing anode”. The anode will disappear because it is eventually coated with an insulator, the reactively formed dielectric compound deposited on the work piece. In the dual magnetron sputtering approach the pair of magnetrons is driven by an AC supply. Therefore, they alternate roles between cathode and anode. So, after a brief time acting as an anode, and receiving a tiny deposition of dielectric, the magnetron will act as a cathode, sputtering conductive material as well as the little bit of dielectric that was deposited during the last time it acted as an anode.

Considerable effort has been expended to develop power supplies whose topologies are optimized for driving these dual magnetron systems. The general approaches used have been both square-wave pulsed supplies and sinusoidal power supplies. U.S. Pat. No. 5,303,139, issued to Mark, describes a pulsed DC voltage source for driving this dual magnetron configuration. U.S. Pat. No. 6,005,218, issued to Walde, et al, and U.S. Pat. No. 5,777,863, issued to Kovalevskii and Kishinevsky, describe pulsed DC current source power supplies for driving dual magnetron power supplies. The pulsed supplies provide the capability of independently regulating the power delivered to each magnetron, enabling the creation of controlled mixtures of materials in the film when dissimilar materials are used for the two magnetron targets. This would allow the creation of films with customized indexes of refraction.

The AC power supplies on the market today control and measure the total power to the two magnetrons. Measurement and control of the power, current and voltage for each magnetron is not yet available in AC supplies. While it is currently common to drive pairs of magnetrons with a single AC phase, there are advantages to delivering power in three or more phases. AC mains power is typically delivered in three phases because the addition of one wire results in the ability to deliver 1.73 times more power. Hence, adding 50% results in a gain of 73%. There are currently many coating systems configured with groupings of three or more magnetrons.

These systems could be converted from DC operation to three phase AC operation with the advantages of the dual magnetron sputtering technique more economically than changing each of the three single magnetrons to dual magnetrons and then adding three separate single phase AC generators. Configurations for driving more than two magnetrons with voltage and current source power supplies are disclosed in U.S. Pat. No. 5,917,286, issued to Scholl and Christie. U.S. Pat. No. 6,005,218, issued to Walde, et al, further discloses means of driving multiple magnetrons with current source power supplies. The above mentioned patents disclose several means of driving multiple magnetrons with multiple phase square waves yet in spite of this, there is no indication that multiple phase AC could be used to drive three or more magnetrons coupled by a common plasma.

A means of generating multiple phase AC is disclosed in U.S. Pat. No. 5,535,906, issued to Drummond. This patent discloses the use of rectified multiple phase AC to drive a DC plasma, but never even hints at the idea of using the AC to drive multiple magnetrons directly. The advantage of using an AC generator is that it is less complex than a pulsed generator, and therefore, less expensive. It is also possible to construct an AC generator which can independently regulate the power delivered to each of the magnetrons it drives, even though that is an advantage commonly attributed to the square wave pulsed approach to driving multiple magnetrons.

It is an object of this invention to drive groups of three or more magnetrons with multiple phase AC power. The current and voltage waveforms delivered by an AC generator would be substantially sinusoidal into a resistive load, however, the load to be driven here is plasma. A magnetron plasma has voltage-current (V-I) characteristics that are significantly non-linear, as well as dynamics which include time-varying impedance. The result is that the actual waveforms from a resonant AC generator driving a plasma rarely appear sinusoidal.

Independent regulation of the power to each magnetron enables the deposition of films composed of three or more conductive metallic or semiconductor materials combined with atoms from one or more reactive gases. Each magnetron target could be different material, and a single reactive gas or mixture of reactive gases, could be combined with the target materials to form a film.

These films, whose composition, and therefore properties, can be precisely controlled, have applications in wear coating for cutting and stamping tools, magnetic coating for data storage media and read/write heads, optical coatings, protective coatings for turbine blades, and decorative coatings. So, this invention enables the commercial deposition of a whole new class of coatings with relatively inexpensive three or more phase AC generators.

### SUMMARY OF THE INVENTION

There is provided by this invention an AC generator for supplying multiphase AC power to multiple magnetrons wherein independent power regulation of each magnetron enables multiple depositions of films within a processing chamber. An AC power supply is connected to each of the magnetron targets disposed in the plasma chamber to independently regulate power to each target wherein the voltages on the targets are periodically reversed such that periodically at least one target at a given time acts as an anode collecting electrons when its voltage is positive relative to the plasma while the other targets act as cathodes collecting ions when their voltage is negative relative to the plasma. A DC bias can be connected to the AC power sources wherein by changing the bias, the energy and flux of ions and electrons to the substrate can be changed to increase the density of the deposited film and its refractive index, and alter the morphology and stress of the film.

### BRIEF DESCRIPTION OF THE DRAWINGS

FIG. 1 shows a prior art plasma processing chamber with one AC power source driving two magnetrons;

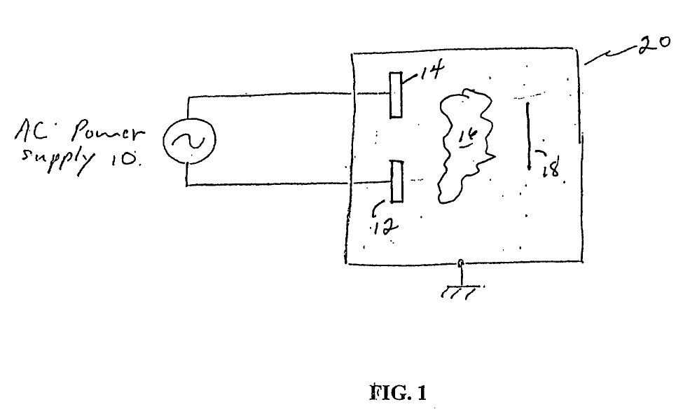

FIG. 2a shows a plasma processing chamber using one arrangement for three AC power sources to drive three magnetrons;

FIG. 2b shows a plasma processing chamber using another arrangement for three AC power sources to drive three magnetrons;

FIG. 3 shows a plasma processing chamber as in FIG. 2a with a DC bias supply; and

FIG. 4 shows a plasma processing chamber driven by four AC phases.

### DETAILED DESCRIPTION OF THE PREFERRED EMBODIMENT

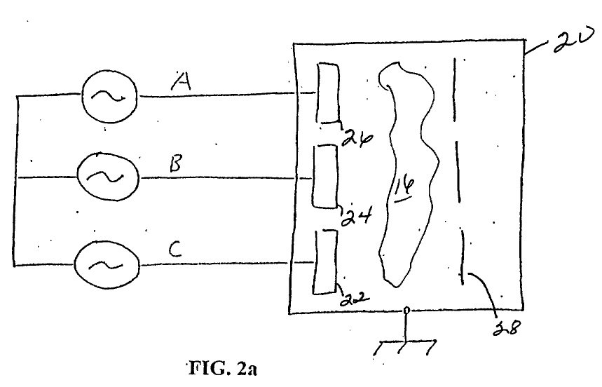

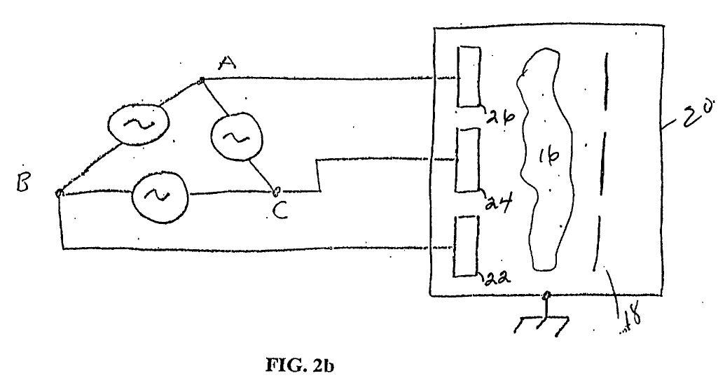

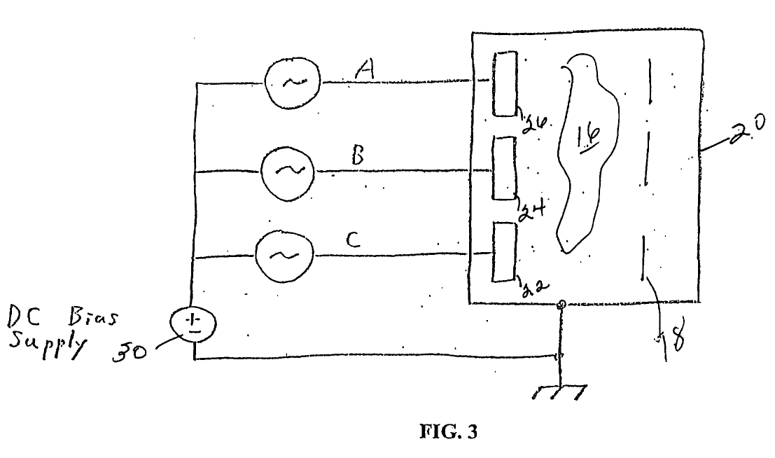

Two examples where three phase AC may be used to drive a magnetron plasma are shown in FIGS. 2a and 2b. FIG. 2a illustrates multiphase AC sources A, B, and C connected in a wye configuration to magnetrons 22, 24, and 26 within the grounded processing chamber 20. FIG. 2b illustrates the same sources and magnetrons configured in a delta configuration. The AC sources have a specific phase relationship to each other. They would typically be phased 120 degrees from the adjacent sources, so the sources could be considered to have absolute phases of 0, 120, and 240 degrees. There may be an advantage in some cases to vary from this phase relationship, perhaps for purposes of controlling the relative power delivered to each of the three electrodes. The magnetrons sputter material when they are at a negative potential, and when the conventional current to them is negative. At least one magnetron will function as an anode at any given time, since at least one source will be positive at any given time. In the above, it should be understood that the AC sources may be separate supplies or may be separate lines emanating from the same supply. A single substrate or multiple substrates such as 28 placed in the chamber in close proximity to the plasma may have thin films deposited from each magnetron Sometimes it is desirable to bias the sputtering power supply with respect to the plasma chamber in order to positively affect the properties of the film deposited by the process. FIG. 3 shows a DC bias supply 30 to the multiphase AC power sources A, B, and C feeding the three magnetrons 22, 24, and 26 in the plasma chamber. The DC bias supply can be added to other arrangements as well. A DC bias can be useful for changing the parameters of the film deposited by the sputtering process. By changing the bias, the energy, and flux of ions and electrons to the substrate can be changed. This effect can be exploited to increase the density of the film, and hence its refractive index. The morphology and stress of the film can also be controlled to some degree by changing the bias level. This enables the film characteristics to be tailored for specific applications.

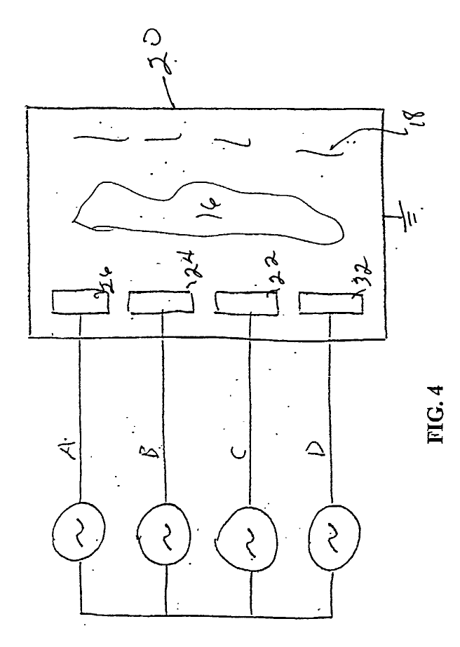

Multiple phase power systems, such as conventional AC mains power, are often three phase systems. However, it is possible to create multiple phase power sources with four or more phases. FIG. 4 shows a plasma processing system driven by a four phase power source. The extension to five or more phases is also possible and will be seen as an extension to the concepts presented in FIGS. 2 and 4.

Industrial plasma processes for applying coatings require accurate control. This implies the need for accurate measurements. Total power can be measured by techniques for measuring power into three phase systems known to those skilled in the art. Modern high frequency multiplier integrated circuits with high accuracy, such as those manufactured by Burr-Brown and Analog Devices, enable the use of these techniques at higher frequencies than typically used for AC mains power. The frequencies of interest are currently typically between 10 and 200 kHz.

Average and/or RIMS current delivered to each magnetron may be determined by gating the measurement, and calculating the average and/or RMS current based on the time that the current to the magnetron is negative. Standard integrated circuits may be used to compute the RMS and average values of a waveform.

Voltage may be a more complicated measurement. Ideally, the RMS voltage delivered to each magnetron would be measured separately. The voltage of interest is really the RMS or average voltage during the time the individual magnetrons sputter. This time period can be determined as the time when the conventional current (positive charges) to the magnetron is negative. The desired voltage measurement would be to the anode. If more than one magnetron is acting as an anode, it may be desirable to average the anode voltages and take the difference between the sputtering magnetron voltage and the average anode voltage. This voltage can then be easily processed into an average or RMS voltage using modern integrated circuits such as op-amps, multipliers, and RMS circuits.

The power delivered to individual magnetrons can be controlled by adjusting the magnitudes, and possibly phases, of the individual voltages driving each of the magnetrons. For example, if the multiple phase AC generation circuit disclosed in U.S. Pat. No. 5,535,906, issued to Drummond were used, then control of the individual magnitudes could be accomplished by pulse width modulation of the individual inverter phases to adjust the relative amplitudes of the phases, and frequency modulation to adjust the overall amplitude.

As can be easily understood from the foregoing, the basic concepts of the present invention may be embodied in a variety of ways. It involves both multiple phase processing techniques as well as devices to accomplish the appropriate processing. In this application, the multiple phase power source techniques are disclosed as part of the results shown to be achieved by the various devices described and as steps that are inherent to utilization. They are simply the natural result of utilizing the devices as intended and described. In addition, while some devices are disclosed, it should be understood that these not only accomplish certain methods but also can be varied in a number of ways. Importantly, as to all of the foregoing, all of these facets should be understood to be encompassed by this discussion.

What I claim is:

1. Apparatus for sputter deposition of a cathode material in a continuous operating mode to form a coating on a substrate, comprising:
a) A grounded plasma chamber in which a plasma is created containing ions and electrons;
b) at least three targets disposed in the plasma chamber containing atoms that can be sputtered therefrom in response to bombardment by ions from the plasma to deposit a film on the surface of at least one substrate in close proximity to the plasma; and
c) an AC power supply connected to each of the targets disposed in the plasma chamber to independently regulate power to each target wherein the voltages on the targets are periodically reversed such that periodically at least one target at a given time acts as an anode collecting electrons when its voltage is positive relative to the plasma while the other targets act as cathodes collecting ions when their voltage is negative relative to the plasma.

2. Apparatus for sputter deposition of a cathode material in a continuous operating mode to form a coating on a substrate as recited in claim 1 wherein after a brief time acting as an anode, and receiving a tiny deposition of dielectric, each target will act as a cathode, sputtering conductive material as well as any dielectric that was deposited during the last time it acted as an anode.

3. Apparatus for sputter deposition of a cathode material in a continuous operating mode to form a coating on a substrate as recited in claim 2 wherein each target is a different material and a single reactive gas or mixture of reactive gases is combined with the target materials to form a film.

4. Apparatus for sputter deposition of a cathode material in a continuous operating mode to form a coating on a substrate as recited in claim 3 wherein the AC power sources are connected in a wye configuration.

5. Apparatus for sputter deposition of a cathode material in a continuous operating mode to form a coating on a substrate as recited in claim 3 wherein the AC power sources are connected in a delta configuration.

6. Apparatus for sputter deposition of a cathode material in a continuous operating mode to form a coating on a substrate, comprising:
a) a grounded plasma chamber in which a plasma is created containing ions and electrons;
b) at least three targets disposed in the plasma chamber each containing atoms that can be sputtered therefrom in response to bombardment by ions from the plasma to deposit a film on the surface of at least one substrate in close proximity to the plasma;
c) an AC power supply connected to each of the targets disposed in the plasma chamber to independently regulate power to each target wherein the voltages on the targets are periodically reversed such that periodically at least one target at a given time acts as an anode collecting electrons when its voltage is positive relative to the plasma while the other targets act as cathodes collecting ions when their voltage is negative relative to the plasma; and
d) a DC bias connected to the AC power sources wherein by changing the bias, the energy and flux of ions and electrons to the substrate can be changed to increase the density of the deposited film and its refractive index.

7. Apparatus for sputter deposition of a cathode material in a continuous operating mode to form a coating on a substrate as recited in claim 6 wherein connecting a DC bias to the AC power sources wherein changing the bias alters the morphology and stress of the film.

8. Apparatus for sputter deposition of a cathode material in a continuous operating mode to form a coating on a substrate as recited in claim 6 wherein after a brief time acting as an anode, and receiving a tiny deposition of dielectric, each target will act as a cathode, sputtering conductive material as well as any dielectric that was deposited during the last time it acted as an anode.

9. Apparatus for sputter deposition of a cathode material in a continuous operating mode to form a coating on a substrate as recited in claim 6 wherein each target is a different material and a single reactive gas or mixture of reactive gases is combined with the target materials to form a film.

10. Apparatus for sputter deposition of a cathode material in a continuous operating mode to form a coating on a substrate as recited in claim 6 wherein the AC power sources are connected in a wye configuration.

11. Apparatus for sputter deposition of a cathode material in a continuous operating mode to form a coating on a substrate as recited in claim 6 wherein the AC power sources arc connected in a delta configuration.

12. A method of sputter deposition of an insulating material on a substrate in a continuous mode consisting of the steps of:
a) providing a grounded chamber in which a plasma is created containing ions and electrons;
b) placing at least three targets in the chamber each containing atoms that can be sputtered therefrom in response to bombardment by ions from the plasma to deposit a film on the surface of at least one substrate in close proximity to the plasma; and
c) connecting an AC power supply to each of the targets disposed in the plasma chamber to independently regulate power to each target wherein the voltages on the targets are periodically reversed such that periodically at least one target at a given time acts as an anode collecting electrons when its voltage is positive relative to the plasma while the other targets act as cathodes collecting ions when their voltage is negative relative to the plasma.

13. A method of sputter deposition of an insulating material on a substrate in a continuous mode as recited in claim 12 further comprising of the step of connecting a DC bias to the AC power sources wherein by changing the bias, the energy and flux of ions and electrons to the substrate can be changed to increase the density of the deposited film and its refractive index.

14. A method of sputter deposition of an insulating material on a substrate in a continuous mode as recited in claim 12 further comprising of the step of connecting a DC bias to the AC power sources wherein changing the bias alters the morphology and stress of the film.

15. A method of sputter deposition of an insulating material on a substrate in a continuous mode as recited in claim 12 wherein each target is a different material and a single reactive gas or mixture of reactive gases is combined with the target materials to form a film.
